(19) United States
(12) Patent Application Publication
(10) Pub. No.: US 2022/0109048 A1
(43) Pub. Date: Apr. 7, 2022

(54) High Voltage Gallium Nitride Field Effect Transistor

(71) Applicants: Zhanming Li, West Vancouver (CA); Yan-Fei Liu, Kingston (CA); Wai Tung Ng, Thornhill (CA)

(72) Inventors: Zhanming Li, West Vancouver (CA); Yan-Fei Liu, Kingston (CA); Wai Tung Ng, Thornhill (CA)

(21) Appl. No.: 17/487,117

(22) Filed: Sep. 28, 2021

Related U.S. Application Data
(60) Provisional application No. 63/088,207, filed on Oct. 6, 2020.

(51) Int. Cl. H01L 29/06; H01L 29/20; H01L 29/778; H01L 29/66

(52) U.S. Cl. CPC H01L 29/0692; H01L 29/66462; H01L 29/7786; H01L 29/2003

(57) ABSTRACT

A gallium nitride (GaN) semiconductor device has first and second electrodes connected to a top metal layer disposed in complementary first and second irregular shapes, each irregular shape including a wide connection area at a first end, a tapered area, and a narrow area at a second end. The first and second irregular shapes are arranged adjacent each other along complementary edges such that a gap between the complementary edges is of substantially constant width. The first and second wide connection areas include pads for wire bond or land grid array electrical connections to external circuitry. The first and second irregular shapes for source and drain metal of a field effect transistor (FET) or high electron mobility transistor (HEMT) allows the width of the gate finger to be short so that electrical current injected from the gate can reach all portions of the gate fingers efficiently during high frequency switching, making the topology suitable for high voltage power devices.

### RELATED APPLICATION

This application claims the benefit of the filing date of Application No. 63/088,207, filed on Oct. 6, 2020, the contents of which are incorporated herein by reference in their entirety.

### FIELD

The invention relates to semiconductor devices for high voltage power switching and for microwave and radio frequency applications. More particularly, the invention relates to design of gallium nitride-based power devices such as field effect transistors and high electron mobility transistors.

### BACKGROUND

Gallium nitride (GaN)-based power devices are finding applications in power electronics for high-frequency and high-power applications owing to their superior material properties such as high polarization-induced two-dimensional electron gas (2DEG) density, high electron saturation velocity, and high critical breakdown electric field. Despite these advantages, a number of limitations exist in prior designs due to the unique lateral device structure of GaN field effect transistors (FETs) and high electron mobility transistors (HEMTs).

In such lateral devices, current flows horizontally through the device. As required current and power ratings of a GaN device increase, the lateral size increases and the electrode pads are wider apart, making it difficult to wire bond to conventional JEDEC frames such TO22/TO263 without wire crossing and wires being overly long, both of which can negatively affect performance.

Another limitation is imposed by the gate width of the GaN device. For effective gate control, the gate width should be of limited size, making it difficult to scale up the device size when current rating is increased. The only option is to increase the number of gate finger counts, but this may make the device overly long in the direction perpendicular to the gate finger.

Additionally, the source-drain spacing requirement for a GaN device is difficult to satisfy due to the limited finger width. In prior multiple metal layer designs, the source and drain pads are located directly above FET fingers. The short gate fingers impose a limit on the pad size as well as source-drain spacing, which in turn imposes a limitation on high voltage design.

### SUMMARY

Described herein are gallium nitride field effect transistor (GaNFET) device layout topologies suitable for high voltage power electronic applications. In some embodiments, the source and drain electrodes have a top metal layer (metal 2, M2) with an interdigitated finger shape with a middle section of the fingers tapered for optimal device performance and suitability for high power device packaging.

According to one aspect of the invention there is provided a semiconductor device, comprising: a semiconductor active area; at least first and second electrodes disposed on the semiconductor active area; a plurality of metal layers and electrically insulating layers alternatingly disposed over the at least first and second electrodes in selected patterns wherein separate electrical connections are provided between each of the at least first and second electrodes and a top metal layer; wherein the top metal layer is disposed in a pattern comprising at least first and second irregular shapes corresponding to the at least first and second electrodes, each irregular shape including a wide connection area at a first end and a narrow area at a second end, and the first and second irregular shapes are arranged adjacent each other along complementary edges such that a gap between the complementary edges is of substantially constant width.

In various embodiments the semiconductor active area comprises GaN, GaN/GaN, GaN/Si, AIGaN/GaN, or GaN/ceramic material.

In one embodiment the first electrode is an anode and the second electrode is a cathode.

In one embodiment first, second, and third electrodes are disposed on the semiconductor active area; wherein the first electrode is a source, the second electrode is a gate, and the third electrode is a drain.

In one embodiment the semiconductor device comprises a field-effect transistor (FET) or a high electron mobility transistor (HEMT).

In one embodiment the wide connection area of the first irregular shape is across the gap from the narrow area of the second irregular shape, and the wide connection area of the second irregular shape is across the gap from the narrow area of the first irregular shape.

In one embodiment the first and second wide connection areas include pads for wire bond or land grid array electrical connections to external circuitry.

In one embodiment a gate width is independent of a distance between source and drain pads disposed on the first and second wide connection areas.

In one embodiment each of the at least first and second irregular shapes includes a tapered area between the wide connection area at the first end and the narrow area at the second end; wherein the tapered area is configured as one or more of a straight taper, a straight taper with an angled corner at one or both ends, a straight taper with a smooth transition at one or both ends, and a smooth curve taper.

In one embodiment the smooth curve taper is selected from a polynomial curve and a hyperbolic curve (tanh( )function).

In one embodiment each of the at least first and second irregular shapes has an outer side that is substantially straight and parallel to a long side of the semiconductor active area; wherein the device is mirrored about an axis corresponding to a long side of the semiconductor active area such that two mirrored devices are provided.

In one embodiment the two mirrored devices are copied and repeated along a direction perpendicular to the electrodes such that a plurality of devices is provided.

According to another aspect of the invention there is provided a method for implementing a semiconductor device, comprising: providing a semiconductor active area; disposing at least first and second electrodes on the semiconductor active area; alternatingly disposing a plurality of metal layers and electrically insulating layers over the at least first and second electrodes in selected patterns wherein separate electrical connections are provided between each of the at least first and second electrodes and a top metal layer; wherein the top metal layer is disposed in a pattern comprising at least first and second irregular shapes corresponding to the at least first and second electrodes, each irregular shape including a wide connection area at a first end and a narrow area at a second end, and the first and second irregular shapes are arranged adjacent each other along complementary edges such that a gap between the complementary edges is of substantially constant width.

In one embodiment of the method the semiconductor active area comprises GaN, GaN/GaN, GaN/Si, AlGaN/GaN, or GaN/ceramic material.

In one embodiment of the method the first electrode is an anode and the second electrode is a cathode.

In one embodiment the method comprises disposing first, second, and third electrodes on the semiconductor active area; wherein the first electrode is a source, the second electrode is a gate, and the third electrode is a drain.

In one embodiment of the method the semiconductor device comprises a field-effect transistor (FET) or a high electron mobility transistor (HEMT).

In one embodiment of the method the first and second wide connection areas include pads for wire bond or land grid array electrical connections to external circuitry.

In one embodiment of the method each of the at least first and second irregular shapes includes a tapered area between the wide connection area at the first end and the narrow area at the second end; wherein the tapered area is configured as one or more of a straight taper, a straight taper with an angled corner at one or both ends, a straight taper with a smooth transition at one or both ends, and a smooth curve taper.

In one embodiment of the method the smooth curve taper is selected from a polynomial curve and a hyperbolic curve (tanh( )function).

In one embodiment of the method each of the at least first and second irregular shapes has an outer side that is substantially straight and parallel to a long side of the semiconductor active area; wherein the device is mirrored about an axis corresponding to a long side of the semiconductor active area such that two mirrored devices are provided.

In one embodiment of the method the two mirrored devices are copied and repeated along a direction perpendicular to the electrodes such that a plurality of devices is provided.

According to another aspect of the invention there is provided a gallium nitride device with two layers of interconnecting metal layers where a top metal layer M2 is vertically connected to a first layer with the following shapes and properties:
the source metal M2 has larger size area on one side of a FET rectangle active area;
the drain metal M2 has larger size area on the other side of the FET rectangle active area;
both the source and drain metal M2 larger areas connect to the opposite end of the FET rectangle active area where smaller metal M2 areas are placed;
for each of the source and drain metal M2, the connection of the smaller and larger areas is tapered with shape of a trapezoid.

In one embodiment, for each of the source and drain metal M2, the connection of the smaller and larger areas is tapered by a smooth shape selected from one or more of:
a straight taper with smooth arcing corners;
a non-straight taper comprising a smooth curve;
a non-straight taper comprising a polynomial curve of order equal to or higher than 2; and
a non-straight taper comprising a tanh( )function.

In accordance with the above embodiments, the gallium nitride device structure may be mirrored substantially symmetrically about an axis at or near the source side or the drain side.

In accordance with the above embodiments, the gallium nitride device structure may be copied and multiplied along a direction perpendicular to device electrode fingers.

### BRIEF DESCRIPTION OF THE DRAWINGS

For a better understanding of the invention, and to show more clearly how it may be carried into effect, embodiments will be described, by way of example, with reference to the accompanying drawings, wherein:

FIGS. 1A and 1B are diagrams showing vertical cross-sections of a GaNFET structure at two locations, according to the prior art.

FIG. 2 is a diagram showing the layout of the GaNFET structure of FIGS. 1A and 1B, in which only two sets of source, gate, and drain fingers are shown for clarity, according to the prior art.

FIG. 3 is a diagram showing the layout of a GaNFET structure, in which only two sets of source, gate, and drain fingers are shown for clarity, according to the prior art.

FIG. 4 is a diagram showing the layout of a device, according to one embodiment.

FIG. 5 is a diagram showing a layout wherein the device of FIG. 4 is mirrored about an axis shown at 515, according to one embodiment.

FIG. 6 is a diagram showing a layout wherein the mirrored device of FIG. 5 is copied and repeated a plurality of time in the direction normal to the gate fingers, according to one embodiment.

### DESCRIPTION

Described herein are structures, layout topologies, and related methods for lateral power electronic devices based on gallium nitride (GaN), such as, but not limited to, GaN, GaN/GaN, GaN/Si, AIGaN/GaN, and GaN/ceramic technologies. Examples of power devices include, but are not limited to, transistors (e.g., field-effect transistor (FET) and high electron mobility transistor (HEMT)), which may be referred to herein generally as GaNFETs with gate, source, and drain electrodes, and diodes/rectifiers with anode and cathode electrodes. Whereas embodiments are described primarily with respect to GaNFETs, the design approach is also applicable to diodes and rectifiers. Embodiments overcome limitations of prior approaches to structures and layout topologies for such devices.

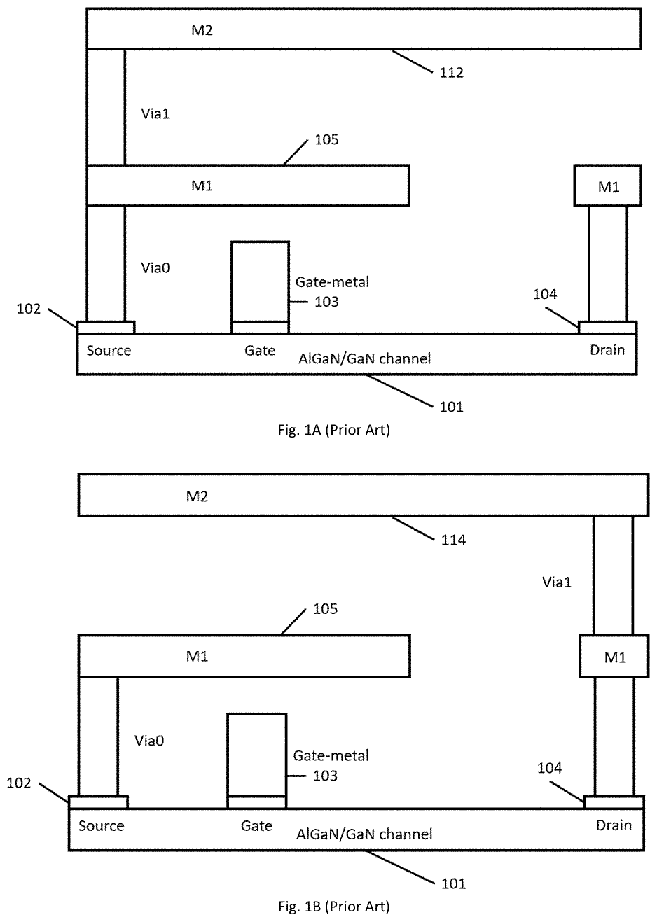

Vertical cross-sectional views of a GaNFET structure according to a typical prior approach are shown in FIGS. 1A and 1B. The device is based on an AlGaN/GaN semiconductor channel 101 with a two-dimensional electron gas (2DEG) structure providing high conductivity and small turn on resistance for the FET. The source 102, gate 103, and drain 104 metal electrodes (also referred to as fingers) are arranged parallel to each other, and these parallel fingers are typically copied in a periodic manner in the direction perpendicular to the fingers to provide high current carrying capacity in a high power device. For a high voltage design, a field plate (FP) metal layer M1 105 is placed above the gate 103 to protect the gate from high electric field. For effective conduction to and from the source and drain, another metal layer M2 is placed above the M1 layer so that conduction can be routed directly from above the source 102 and drain 104 through metal vertical interconnect access (VIA) holes. This is shown for the source metal M2 112 in FIG. 1A and for the drain metal M2 114 in FIG. 1B, wherein each figure is representative of a cross section at a different location of the device.

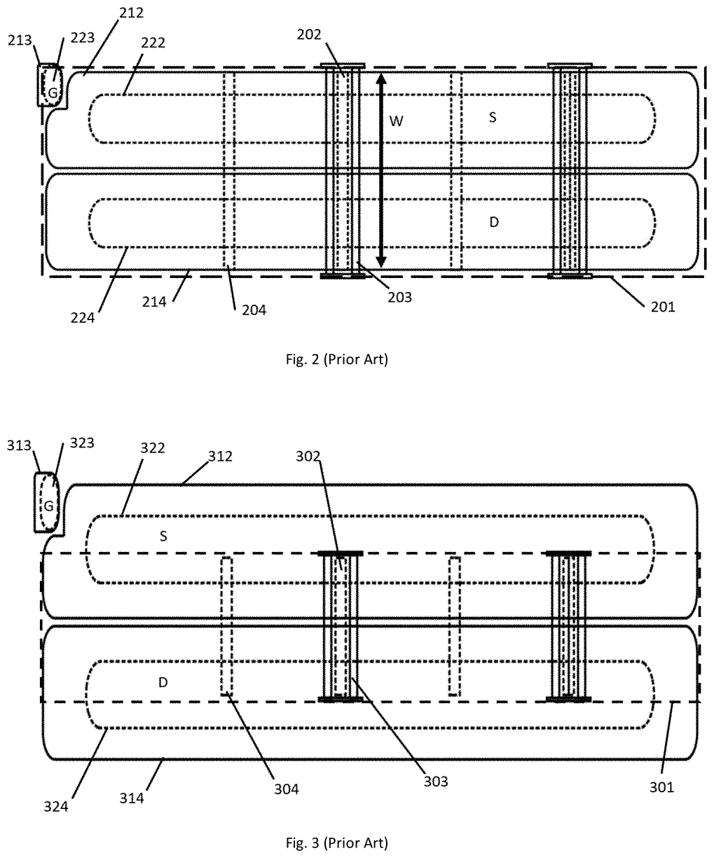

FIG. 2 is a diagram showing the layout of a GaNFET design according to a prior approach, based on the structure shown in FIGS. 1A and 1B, with source (S) 202, gate (G) 203, and drain (D) 204 fingers arranged within an active FET area 201. For simplicity only two sets of source, gate, and drain fingers are shown, however in a typical device there would be many sets of source, gate, and drain fingers. It can be seen that the source metal M2 212 and the drain metal M2 214 are placed on top of the active FET area 201. The source metal M2 212 is in contact with the source finger 202 and the drain metal M2 214 is in contact with the drain finger 204. Typically the metal M2 layer is covered on top with an insulating layer and pads are provided by opening the insulating layer on top of metal M2 allowing access of land grid array (LGA) metal or bonding wires to contact the metal M2 layer. The arrangement is such that source electrode pad 222 and the drain electrode pad 224 do not take up more wafer space than the active FET area 201. The gate metal M2 213 and pad 223 are typically disposed behind the source metal M2 and away from the high voltage drain. Due to the non-crossing connectivity, the gate metal M2 213 is connected to the gate finger 203 through a metal layer M1 105, as shown in FIGS. 1A and 1B. For effective gate control, the width W (see arrows in FIG. 2)of the gate finger 203 must be short so that electrical current injected from the gate pad 223 can reach all portions of the gate fingers efficiently during high frequency switching. Another important aspect of the layout is the spacing between the source pad 222 and the drain pad 224. These pads must be separated by a distance sufficient to prevent sparking or dielectric break down. However, it is clear that short gate fingers and large source-drain spacing are conflicting requirements.

FIG. 3 is a diagram showing the layout of a GaNFET design according to another prior approach, with source 302, gate 303, and drain 304 fingers arranged within an active FET area 301. This approach is similar to that of FIG. 2, except the contact pads are enlarged and separated farther apart along the gate finger direction. As in the design of FIG. 2, the gate metal M2 313 and gate pad 323 are disposed behind the source metal M2 312 and away from the high voltage drain. This layout overcomes the drawback of the small source-drain spacing in the design of FIG. 2. This is achieved by enlarging the source metal M2 312 and the drain metal M2 314 in the direction parallel to the fingers, so that the source and drain electrode pads 322, 324 are spaced farther apart. However, in this prior design a large amount of wafer area beyond the active FET area 301 is used, therefore wasting valuable GaN wafer area.

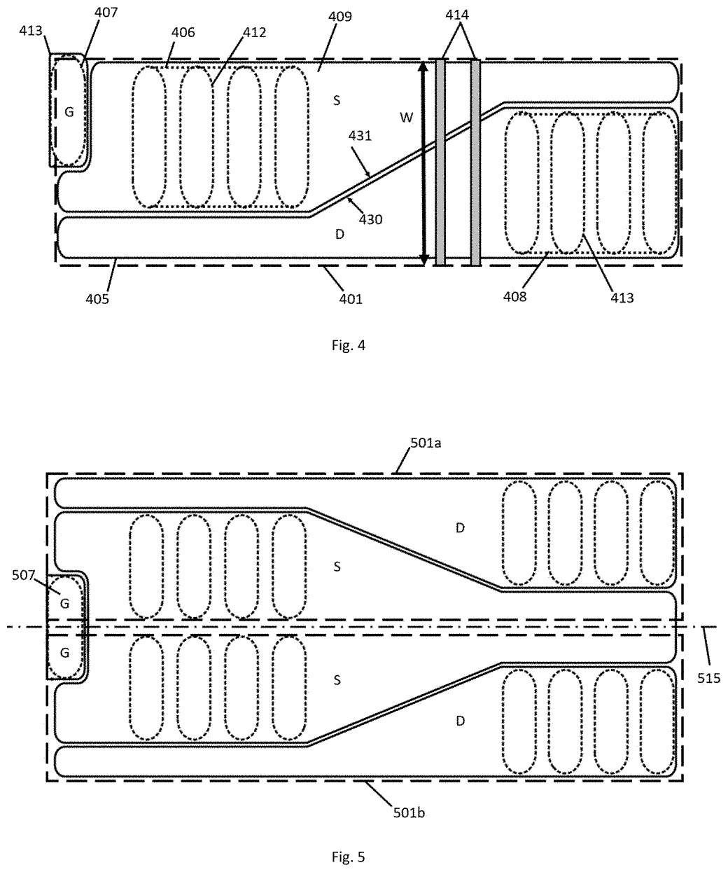

FIG. 4 is a diagram showing a layout of a GaNFET according to one embodiment of the invention. Referring to FIG. 4, this embodiment includes an active FET area 401, gate metal M2 413, gate pad 407, source metal M2 layer 409 and drain metal M2 layer 405, source electrode pads 406 or 412, and drain electrode pads 408 or 413. To simplify the figure only two sets of gate, source, and drain fingers are shown as shaded areas 414, however, typically there would be many sets (e.g., up to 200 or more sets). The arrow W indicates the gate width. It can be seen that the source metal M2 layer 409 and the drain metal M2 layer 405 are disposed in non-rectangular (i.e., irregular) shapes. For each of the source and drain metal M2, the shape provides a wide area that accommodates the pads, a tapered region, and a narrow area. For efficient use of wafer area, the shapes of the source and drain metal M2 layers 409, 405 are substantially complementary or symmetrical about the gap separating them. Since the metal M2 may be deposited as a thick layer, e.g., ranging from 3-10 μm, it can efficiently inject current from the electrode pads in the wide area to the narrow area. The electrode pads 406 and 408 are placed on the wide areas so that large pad areas can be used.

Unlike prior designs, according to embodiments, the source pad and drain pad opening on top of the M2 metal layer are well separated while avoiding exceedingly long finger width, thus providing for effective gate control. That is, the-non-rectangular shapes of the source and drain metal M2 allows the width W of the gate fingers 414 to be short without reducing separation between the source pad 406 or 412 and the drain pad 408 or 413. For example, in some embodiments the gate width W can be set independently of or without the need to adjust the distance between the source and drain pads, wherein different gate widths can be accommodated by varying the width and optionally the taper of the source and drain metal M2 while leaving the distance between source and drain pads substantially constant. In addition, embodiments provide effective gate control since electrical current injected from the gate pad 407 can reach all portions of the gate fingers efficiently during high frequency switching. Thus, unlike prior designs such as that shown in FIG. 2, short gate fingers and large source-drain spacing are not conflicting requirements, since reduction of the gate width W in e.g., the embodiment of FIG. 4, would not affect source-drain pad separation. Since the metal M2 may be deposited as a thick layer (e.g., 3-10 μm) it can efficiently inject current from the source and drain electrode pads in the wide area to the narrow area. Also, embodiments provide for the source electrode pad 406 or 412 and the drain electrode pad 408 or 413 to be separated by a greater distance than prior designs, thereby preventing sparking or dielectric break down.

The embodiment of FIG. 4 may be configured to support both wire bonding or LGA packaging design. In the case of wire bonding, single large pads 406, 408 are provided in the wide areas of the metal M2. For LGA, multiple metal bumps 412, 413 are provided in the wide areas of the metal M2. An advantage of this embodiment is that the source pads 406 or 412 and drain pads 408 or 413 are separated far away as required for high voltage devices. For example, the source and drain pads may be separated by 800 p.m or more according to embodiments described herein. Since the source and drain pads are on the larger areas of the M2 metal, sufficient pad area can be utilized for better FET performance. A further advantage is that the layout topology is suitable for packaging for both LGA and wire bonding. For example, for JEDEC packaging such as TO220 and TO263, it is required that wires from each electrode be localized in concentrated areas so that wires do not cross each other. For LGA, there is an advantage in that the metal bumps are all localized and printed circuit board (PCB) layout can use a simple single layer metal trace in a non-crossing manner.

It will be appreciated that the irregular shape of the source metal M2 layer 409 and drain metal M2 layer 405, and particularly the tapered area shown generally at 430, 431 in the embodiment of FIG. 4 is only one of many possible configurations that may be used to connect the wide area to the narrow area of each of the source and drain metal M2. In other embodiments the angular corner at each end of the taper may be replaced by a smooth transition such as an arc, or instead of being straight, the entire tapered area may be replaced by a smooth curve, such as a polynomial curve (e.g., a polynomial of order 2 or higher) or a hyperbolic curve (tanh( )function), etc. that connects the wide area to the narrow area, or any combination of such shapes. Use of smooth transitions and/or smooth curves enhances efficient injection of current from the electrode pads in the wide area to the narrow area. In other embodiments the entire source and drain metal layer M2 may be implemented with a continuous linear or non-linear taper across the device, resulting in a completely or substantially continuous transition from the wide area that accommodates the pads to the narrow area at the opposite end.

FIG. 5 is diagram showing the layout of another embodiment where the layout of FIG. 4 is mirrored (i.e., symmetrical) about an axis shown by the dashed line 515, resulting in two devices. It should be noted that when mirroring, the active areas 501a, 501b of the devices (where S, G, D finger arrays are located within) are separated so that a metal 1(M1) connector can run from the gate M2 pad (507) to the gate fingers within the active areas 501a, 501b. The gate M2 pad for each device may be disposed as a single metal piece for ease of wire bonding or metal bumping.

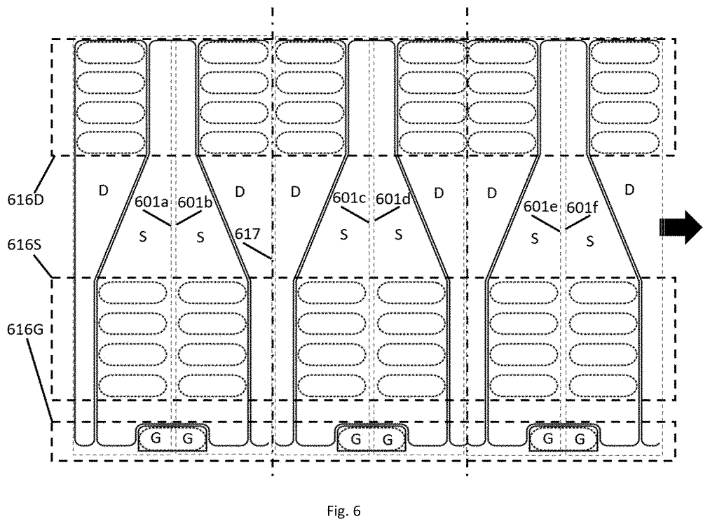

FIG. 6 is another embodiment where the layout in FIG. 5 is copied and repeated three times with respect to edge 617, resulting in six devices. The large arrow at the right indicates that the structure can be repeated many more times than shown resulting in many more devices as required to make a high voltage power device. FET active areas are shown with dashed rectangles 601a-601f. The FET active areas may be separated and isolated from each other. In some embodiments the M2 metal layer may optionally be connected together across devices to increase current injection uniformity. For this layout, LGA packaging has the benefit of being able to use straight PCB traces to the gate, source, and drain, e.g., as shown by the respective dashed rectangles 616G, 616S, and 616D, to connect to the metal bumps. Such an embodiment may also be configured for wire bonding, e.g., for a large JEDEC frame or for power modules, by providing electrode pads instead of metal bumps, so that bonding wires can be well separated in a non-crossing manner.

### EQUIVALENTS

While the invention has been described with respect to illustrative embodiments thereof, it will be understood that various changes may be made to the embodiments without departing from the scope of the invention. Accordingly, the described embodiments are to be considered exemplary and the invention is not to be limited thereby.

1. A semiconductor device, comprising:
a semiconductor active area;
at least first and second electrodes disposed on the semiconductor active area;
a plurality of metal layers and electrically insulating layers alternatingly disposed over the at least first and second electrodes in selected patterns wherein separate electrical connections are provided between each of the at least first and second electrodes and a top metal layer;
wherein the top metal layer is disposed in a pattern comprising at least first and second irregular shapes corresponding to the at least first and second electrodes, each irregular shape including a wide connection area at a first end and a narrow area at a second end, and the first and second irregular shapes are arranged adjacent each other along complementary edges such that a gap between the complementary edges is of substantially constant width.

2. The semiconductor device of claim 1, wherein the semiconductor active area comprises GaN, GaN/GaN, GaN/Si, AIGaN/GaN, or GaN/ceramic material.

3. The semiconductor device of claim 1, wherein the first electrode is an anode and the second electrode is a cathode.

4. The semiconductor device of claim 1, comprising first, second, and third electrodes disposed on the semiconductor active area;
wherein the first electrode is a source, the second electrode is a gate, and the third electrode is a drain.

5. The semiconductor device of claim 4, wherein the semiconductor device comprises a field-effect transistor (FET) or a high electron mobility transistor (HEMT).

6. The semiconductor device of claim 1, wherein the wide connection area of the first irregular shape is across the gap from the narrow area of the second irregular shape, and the wide connection area of the second irregular shape is across the gap from the narrow area of the first irregular shape.

7. The semiconductor device of claim 1, wherein the first and second wide connection areas include pads for wire bond or land grid array electrical connections to external circuitry.

8. The semiconductor device of claim 1, wherein each of the at least first and second irregular shapes includes a tapered area between the wide connection area at the first end and the narrow area at the second end;
wherein the tapered area is configured as one or more of a straight taper, a straight taper with an angled corner at one or both ends, a straight taper with a smooth transition at one or both ends, and a smooth curve taper.

9. The semiconductor device of claim 8, wherein the smooth curve taper is selected from a polynomial curve and a hyperbolic curve (tanh( )function).

10. The semiconductor device of claim 4, wherein a gate width is independent of a distance between source and drain pads disposed on the first and second wide connection areas.

11. The semiconductor device of claim 1, wherein each of the at least first and second irregular shapes has an outer side that is substantially straight and parallel to a long side of the semiconductor active area;
wherein the device is mirrored about an axis corresponding to a long side of the semiconductor active area such that two mirrored devices are provided.

12. The semiconductor device of claim 11, wherein the two mirrored devices are copied and repeated along a direction perpendicular to the electrodes such that a plurality of devices is provided.

14. A method for implementing a semiconductor device, comprising:
providing a semiconductor active area;
disposing at least first and second electrodes on the semiconductor active area;
alternatingly disposing a plurality of metal layers and electrically insulating layers over the at least first and second electrodes in selected patterns wherein separate electrical connections are provided between each of the at least first and second electrodes and a top metal layer;
wherein the top metal layer is disposed in a pattern comprising at least first and second irregular shapes corresponding to the at least first and second electrodes, each irregular shape including a wide connection area at a first end and a narrow area at a second end, and the first and second irregular shapes are arranged adjacent each other along complementary edges such that a gap between the complementary edges is of substantially constant width.

15. The method of claim 14, wherein the semiconductor active area comprises GaN, GaN/GaN, GaN/Si, AlGaN/GaN, or GaN/ceramic material.

16. The method of claim 14, wherein the first electrode is an anode and the second electrode is a cathode.

17. The method of claim 14, comprising first, second, and third electrodes disposed on the semiconductor active area;
wherein the first electrode is a source, the second electrode is a gate, and the third electrode is a drain.

18. The method of claim 17, wherein the semiconductor device comprises a field-effect transistor (FET) or a high electron mobility transistor (HEMT).

19. The method of claim 14, wherein the first and second wide connection areas include pads for wire bond or land grid array electrical connections to external circuitry.

20. The method of claim 17, wherein a gate width is independent of a distance between source and drain pads disposed on the first and second wide connection areas.

21. The method of claim 14, wherein each of the at least first and second irregular shapes includes a tapered area between the wide connection area at the first end and the narrow area at the second end;
wherein the tapered area is configured as one or more of a straight taper, a straight taper with an angled corner at one or both ends, a straight taper with a smooth transition at one or both ends, and a smooth curve taper.

22. The method of claim 21, wherein the smooth curve taper is selected from a polynomial curve and a hyperbolic curve (tanh( )function).

23. The method of claim 14, wherein each of the at least first and second irregular shapes has an outer side that is substantially straight and parallel to a long side of the semiconductor active area;
wherein the device is mirrored about an axis corresponding to a long side of the semiconductor active area such that two mirrored devices are provided.

24. The method of claim 23, wherein the two mirrored devices are copied and repeated along a direction perpendicular to the electrodes such that a plurality of devices is provided.
